(19) United States
(12) Patent Application Publication
(10) Pub. No.: US 2016/0013056 A1
(43) Pub. Date: Jan. 14, 2016

(54) HEAT TREATMENT APPARATUS AND HEAT TREATMENT METHOD

(71) Applicant: TOKYO ELECTRON LIMITED, Minato-ku, Tokyo (JP)

(72) Inventors: Shigeru KASAI, Nirasaki (JP); Hitoshi MIURA, Ibaraki (JP)

(73) Assignee: TOKYO ELECTRON LIMITED, Minato-ku, Tokyo (JP)

(21) Appl. No.: 14/771,046

(22) PCT Filed: Dec. 26, 2013
(86) PCT No.: PCT/JP2013/085335

§ 371 Date: Aug. 27, 2015

(30) Foreign Application Priority Data
Feb. 27, 2013 (JP) 2013-037138

(51) Int. Cl. H01L 21/02; H05B 6/78; H05B 6/80; H05B 6/70

(52) U.S. Cl. CPC H01L 21/02667; H05B 6/70; H05B 6/78; H05B 6/80; H01L 21/02532

(57) ABSTRACT

A heat treatment apparatus includes processing chambers into which microwaves with an effective wavelength of λg are introduced. The processing chambers are arranged parallel to each other. The length from an inner wall surface of one end of each processing chamber in the lengthwise direction to an inner wall surface of the other end thereof is m×λg/2 (m being a positive integer). An antenna sending microwave oscillation into the processing chambers is separated by λg/4+p×λg/2 (p being a positive integer including 0) from the inner wall surface of the end part in the lengthwise direction of each processing chamber. The processing chambers are disposed to be offset by λg/(2×n) (n being the number of the processing chambers) from each other in the lengthwise direction, when the processing chambers are seen to overlap with each other in a perpendicular direction to the lengthwise direction of each processing chamber.

### CROSSREFERENCE

This application is a National Stage Application of, and claims priority to, PCT Application No. PCT/JP2013/085335, filed on Dec. 26, 2013, entitled “HEAT TREATMENT APPARATUS AND HEAT TREATMENT METHOD,” which claims priority to Japanese Patent Application No. 2013-037138, filed on Feb. 27, 2013. The foregoing patent applications are herein incorporated by reference by entirety for all purposes.

### FIELD OF THE INVENTION

The present invention relates to a heat treatment apparatus and a heat treatment method that use a microwave.

### BACKGROUND OF THE INVENTION

In a manufacturing process of a large panel such as a FPD (flat panel display) panel, PV (photovoltaics) panel or the like, a silicon thin film is formed in a large area on a surface of a large glass substrate by CVD (chemical vapor deposition). Then, a plurality of TFTs (thin-film transistors) or PIN diodes are formed by using the silicon thin film. Here, since the silicon thin film is formed on the glass substrate, not on a semiconductor wafer, a crystal does not grow and an amorphous state is maintained.

Meanwhile, a high mobility and a high mutual conductance (gm) are required in the TFTs in the FPD panel corresponding to, e.g., the super Hi-Vision. However, a silicon thin film in an amorphous state (hereinafter, referred to as “amorphous silicon thin film”) has a problem that a mobility and a mutual conductance are low. Accordingly, it has been suggested that the amorphous silicon thin film is made to be single-crystallized or poly-crystallized by heat treatment.

For example, a low temperature heat treatment technology using laser light irradiation is usually employed in the heat treatment of the amorphous silicon thin film. However, since a laser light easily interferes and a spot diameter is small, a control of a given in-plane heat amount is difficult. Further, in a large silicon thin film, a uniform heat treatment is difficult to be performed on the silicon thin film, and a uniform crystallization is also difficult. As a result, there arises a problem such as a threshold voltage value becoming non-uniform in the TFTs.

Recently, since the microwave is more easily controlled than a laser light, a heat treatment technique using a microwave has developed and the microwave has been applied to a heat treatment of the amorphous silicon thin film. In a case where a heat treatment technique using a microwave is employed, the microwave is introduced into a processing space, and the microwave is absorbed to the amorphous silicon thin film on a glass substrate by exposing the glass substrate to the processing space (see, e.g., Patent Documents 1 and 2).

### PATENT DOCUMENT

Patent Document 1: Japanese Patent Application Publication No. 1993-90178

Patent Document 2: Japanese Patent Application Publication No. 2009-91604

However, the introduced microwave is reflected at an inner wall surface forming the processing space, which results in generation of a standing wave in the processing space. If the standing wave is generated, a portion of the amorphous silicon thin film corresponding to an antinode of the standing wave is strongly heated and a portion of the amorphous silicon thin film corresponding to a node of the standing wave is little heated. Accordingly, a uniform heat treatment of the amorphous silicon thin film becomes difficult.

### SUMMARY OF THE INVENTION

In view of the above, the present invention provides a heat treatment apparatus and a heat treatment method which can perform a uniform heat treatment onto a target object by using a microwave.

In order to achieve the above object, there is provided a heat treatment apparatus, including: a plurality of tube-shaped processing chambers into which a microwave is introduced, the processing chambers being arranged parallel to each other and each having an opening part facing a target object, wherein the processing chambers are disposed, when the processing chambers are seen so as to overlap with each other in a perpendicular direction to a lengthwise direction of each of the processing chambers, to be offset from each other in the lengthwise direction so that phases of standing waves generated in the processing chambers do not coincide with each other.

In a case where the number of the processing chambers is n, if an effective wavelength of the microwave is assumed to be λg, the processing chambers may be offset by λg/(2×n) from each other in the lengthwise direction.

Each of the processing chambers may include an antenna configured to oscillate the microwave in the corresponding processing chamber, wherein in each of the processing chambers, a length from an inner wall surface of one end of the corresponding processing chamber in the lengthwise direction to an inner wall surface of ends thereof is m×λg/2, where m is a positive integer, and wherein in each of the processing chambers, the antenna is separated by λg/4+p×λg/2, where p is a positive integer including 0, from an inner wall surface of an end portion in the lengthwise direction of the corresponding processing chamber.

Antennas in the respective processing chambers may be disposed so as not to overlap with each other, when the respective processing chambers are seen so as to overlap with each other in the perpendicular direction to the lengthwise direction of the respective processing chambers.

Antennas in the respective processing chambers may be arranged at a substantially regular interval in the lengthwise direction of the respective processing chambers, when the respective processing chambers are seen so as to overlap with each other in the perpendicular direction to the lengthwise direction of the respective processing chambers.

Each of the processing chambers may include a groove-shaped choke structure at a side of the opening part, and a depth of the choke structure may be λg/4.

Each of the processing chambers may include a slot provided to suppress a microwave transmission from the corresponding processing chamber toward the target object in a wall portion near the opening part.

The heat treatment apparatus may further includes: a preheating device configured to preheat the target object before the microwave is absorbed to the target object by the processing chambers.

In order to achieve the above object, there is provided a heat treatment method to be performed in a heat treatment apparatus including a plurality of tube-shaped processing chambers into which a microwave is introduced, the processing chambers being arranged parallel to each other and each having an opening part facing a target object, the method including: allowing phases of standing waves generated in the respective processing chambers, which are observed to be in an overlapped state when the processing chambers are seen so as to overlap with each other from a perpendicular direction to a lengthwise direction of the processing chambers, to be shifted from each other.

When the microwave is introduced into one of the processing chambers, the microwave may not be introduced into the other processing chambers.

The target object may be preheated before the microwave is absorbed to the target object by the processing chambers.

### EFFECT OF THE INVENTION

In accordance with the present invention, when the processing chambers are seen so as to overlap with each other from the perpendicular direction to the lengthwise direction of the processing chambers, phases of standing waves generated in the processing chambers do not coincide with each other. Therefore, a sum of amplitudes in the phases of the standing waves corresponding to the each part of the target object almost keeps a balance, so that the heat amount given by the standing waves can be uniformalized in each part of the target object. As a result, a uniform heat treatment can be performed onto the target object by using a microwave.

### BRIEF DESCRIPTION OF THE DRAWINGS

FIG. 1 is a perspective view showing a schematic configuration of a heat treatment apparatus in accordance with an embodiment of the present invention.

FIG. 2 is a plan view showing a schematic configuration of the heat treatment apparatus in accordance with the present embodiment.

FIG. 3 is a cross-sectional view taken along with a line III-III of FIG. 2.

FIG. 4 is a graph showing an overlapped state of standing waves generated in processing chambers in the heat treatment apparatus of FIG. 1.

FIG. 5 is a view showing an arrangement state of megnetrons in the heat treatment apparatus of FIG. 1.

FIG. 6 is a plan view showing a schematic configuration of the first modified example of the heat treatment apparatus of FIG. 1.

FIG. 7 is a graph showing an overlapped state of standing waves generated in processing chambers in a heat treatment apparatus of FIG. 6.

FIG. 8 is a timing chart showing timings at which microwaves are generated by the magnetrons of the processing chambers.

FIG. 9A is a perspective view showing a schematic configuration of one example of a processing chamber having a microwave leakage prevention mechanism.

FIG. 9B is a cross-sectional view taken along a line IXB-IXB of FIG. 9A.

FIG. 10 is a perspective view showing a schematic configuration of another example of a processing chamber having the microwave leakage prevention mechanism.

FIG. 11 is a cross-sectional view showing a schematic configuration of the second modified example of the heat treatment apparatus of FIG. 1.

### DETAILED DESCRIPTION OF THE EMBODIMENTS

Hereinafter, embodiments of the present invention will be described with respect to the accompanying drawings.

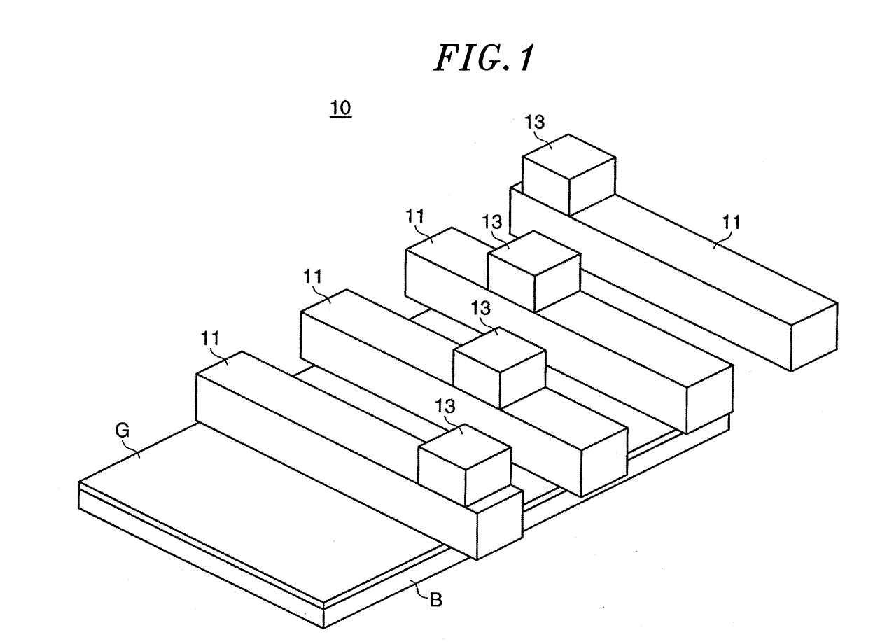

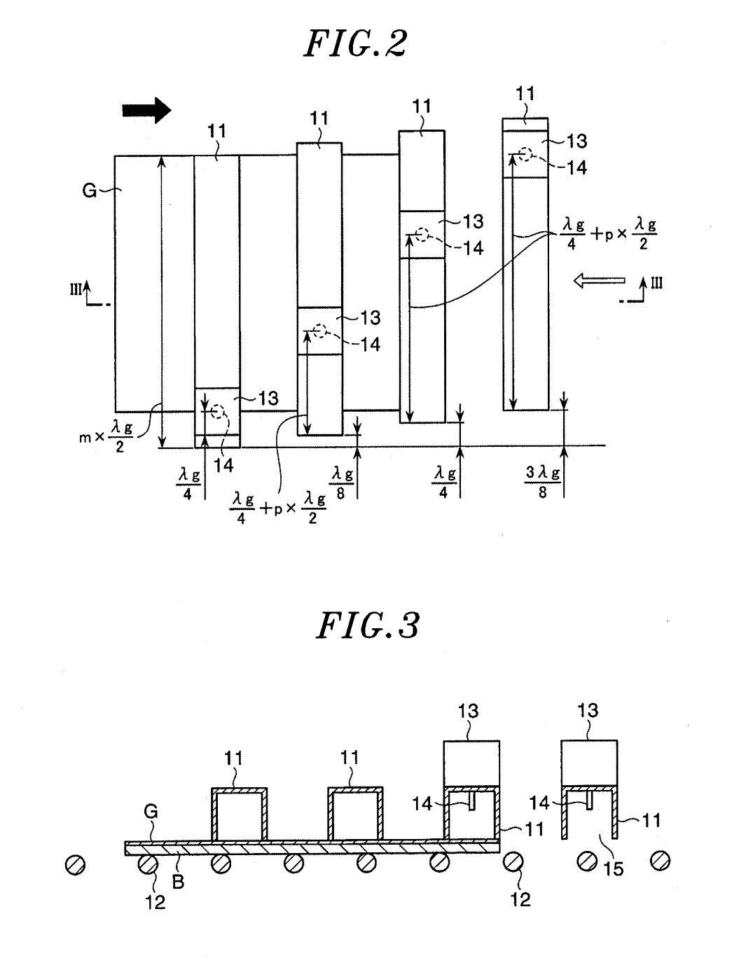

FIGS. 1 to 3 show a schematic configuration of a heat treatment apparatus in accordance with the present embodiment, wherein FIG. 1 is a perspective view, FIG. 2 is a plan view, and FIG. 3 is a cross-sectional view taken along with a line III-III of FIG. 2.

In FIGS. 1 to 3, a heat treatment apparatus 10 includes a plurality of tube-shaped processing chambers 11, and a plurality of rollers 12 arranged below the processing chambers 11 to be opposite to the processing chambers 11. The processing chambers 11 are disposed parallel to each other in a lengthwise direction of the processing chambers (hereinafter, simply referred to as “lengthwise direction”) and disposed at a substantially regular interval in a perpendicular direction to the lengthwise direction. The rollers 12 transfer a plate-shaped susceptor B made of a metal and a substrate G mounted on the susceptor B together along an arrangement direction of the processing chambers 11 (along a black arrow in FIG. 2).

A gap between the processing chambers 11 and rollers 12 is set to be a little bigger than the thickness of the substrate G. The substrate G passes through the gap between the processing chambers 11 and rollers 12. The substrate G is made of a glass, and the thickness of the substrate G is, e.g., 0.5 mm. An amorphous silicon thin film is formed on the surface of the substrate G. The thickness of the amorphous silicon thin film is, e.g., 1 μm.

A magnetron 13 for generating a microwave is arranged on the top surface of each of the processing chambers 11. The magnetron 13 has a rod-shaped antenna 14 protruding into the processing chamber 11. The antenna 14 oscillates a microwave having a frequency of any one of 900 MHz to 20 GHz toward the inside of the processing chamber 11, and.

Each of the processing chambers 11 has a rectangular parallelepiped shape. A length in a lengthwise direction, i.e., a length from the inner wall surface of one end to the inner wall surface of the other end is set to m×λg/2 (where m is a positive integer and λg is an effective wavelength of a microwave). In FIG. 2, a dimension of the length in the lengthwise direction of the processing chambers 11 appears, for simple explanation, to be a distance from the outer wall surface of one end to the outer wall surface of the other end, but it actually represents a distance from the inner wall surface of one end to the inner wall surface of the other end. In each of the processing chambers 11, the antenna 14 of the magnetron 13 is disposed to be separated by λg/4+p×λg/2 (p is a positive integer including 0) from the inner wall surface of one end or the other end of the corresponding processing chamber 11.

Each of the processing chambers 11 includes an opening part 15 formed by removing the bottom wall that faces the rollers 12. The opening part 15 faces the substrate G that is transferred. When the opening part 15 and the substrate G face to each other, the processing chamber 11 is sealed by the substrate G. Since the susceptor B on which the substrate G is mounted is made of a metal, a microwave is transmitted to the susceptor B, which serves as an electromagnetic wall. As a result, the processing chamber 11 functions as a waveguide.

When the processing chamber 11 functions as a waveguide, a microwave oscillated toward the inside of the processing chamber 11 proceeds, as a traveling wave, along the lengthwise direction in the inside of the processing chamber 11. Further, the microwave is reflected by the inner wall surface of one end or the other end, and the reflected wave also proceeds along the lengthwise direction. Since the distance from the inner wall surface of one end of the processing chamber 11 to the inner wall surface of the other end thereof is set to m×λg/2, the traveling wave and the reflected wave overlap with each other in the processing chamber 11, and a standing wave having a wavelength of λg/2 is generated along the lengthwise direction in the processing chamber 11. However, the antenna 14 is separated by λg/4+p×λg/2 (p is a positive integer including 0) from the inner wall surface of one end or the other end of the processing chamber 11, and the inner wall surface of the one end or the other end is a fixed end. Therefore, there is generated a standing wave of a single mode in which nodes are formed at the inner wall surface of one end and the inner wall surface of the other end.

In the heat treatment apparatus 10, when the substrate G is transferred by the rollers 12, the standing waves in the processing chambers 11 are absorbed into the amorphous silicon thin film of the substrate G to heat the amorphous silicon thin film.

Further, in the heat treatment apparatus 10, the processing chambers 11 are offset from each other in the lengthwise direction. Specifically, the adjacent processing chambers 11 are disposed offset from each other by λg/(2×n) (where n is the number of the processing chambers 11) in the lengthwise direction. As shown in FIGS. 1 to 3, four processing chambers 11 are provided in the present embodiment, so that the three processing chambers 11 are offset from the leftmost processing chamber 11 by λg/8, λg/4, 3λg/8 as they are positioned further away from the leftmost processing chamber 11.

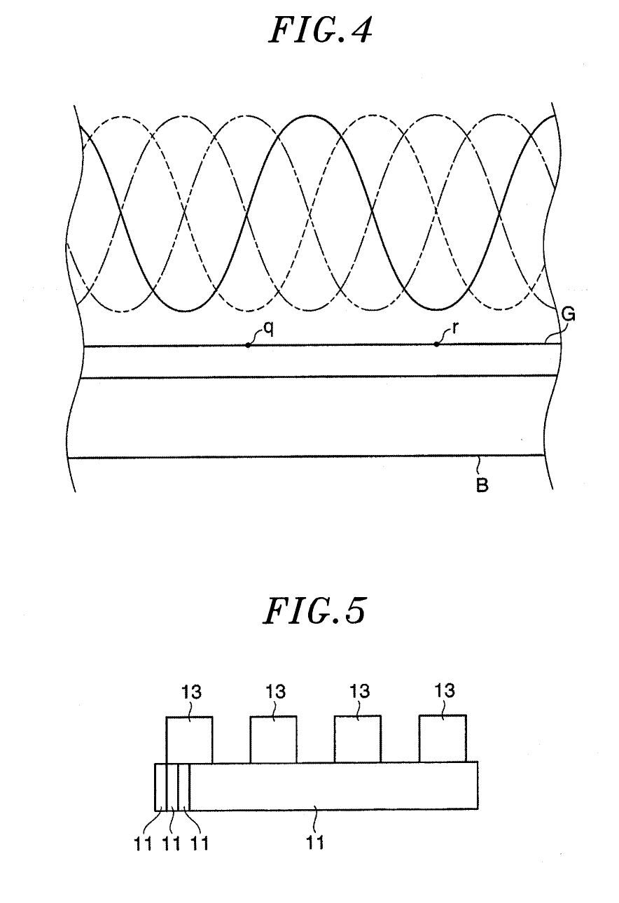

A wavelength of the standing waves generated in the respective processing chambers 11 is λg/2. Therefore, if the respective processing chambers 11 are offset as described above, the standing waves in the respective processing chambers 11 are equally deviated in a length of one wavelength of the standing waves when the respective processing chambers 11 are seen so as to overlap with each other in a perpendicular direction to the lengthwise direction (when the respective processing chambers 11 are seen in a direction of a white arrow in FIG. 2). Specifically, if the processing chambers 11 in FIG. 2 are assumed, sequentially from the leftmost processing chamber 11, to be the first processing chamber 11, the second processing chamber 11, the third processing chamber 11 and the fourth processing chamber 11, as shown in FIG. 4, a phase of a standing wave (solid line) of the first processing chamber 11, a phase of a standing wave (broken line) of the second processing chamber 11, a phase of a standing wave (one dot chain line) of the third processing chamber 11, a phase of a standing wave (two-dot chain line) of the fourth processing chamber 11 are shifted equally (by 90°) from each other in a phase (360°) of one wavelength.

At this time, in FIG. 4, the substrate G passing below the processing chambers 11 forwardly are exposed to the respective standing waves through the opening parts 15. A heat amount for each part of the substrate G is almost proportional to a sum of amplitudes in phases of the respective standing waves corresponding to the each part. Since the phases of the standing waves are equally shifted from each other, the sum of amplitudes in phases of the respective standing waves corresponding to the each part of the substrate G almost keeps a balance and the heat amount can be uniformalized for each part of the substrate G.

For example, at a part “q” of the substrate G in FIG. 4, amplitudes of standing waves in the first processing chamber 11 and the third processing chamber 11 are 0, and amplitudes of standing waves in the second processing chamber 11 and the fourth processing chamber 11 are maximum. Accordingly, the part “q” is given a heat amount corresponding to twice of the maximum amplitude of the standing wave. Moreover, at a part “r” of the substrate G in FIG. 4, amplitudes of standing waves in the first processing chamber 11 and the third processing chamber 11 are maximum, and amplitudes of standing waves in the second processing chamber 11 and the fourth processing chamber 11 are 0. Accordingly, the part “r” is also given a heat amount corresponding to twice of the maximum amplitude of the standing wave.

That is, in accordance with the heat treatment apparatus 10 of the present embodiment, when the processing chambers 11 are seen in the direction of the white arrow in FIG. 2, the phases of the standing waves generated in the respective processing chambers 11 do not coincide with each other, and are equally shifted from each other in a phase of one wavelength of the standing waves. Accordingly, the heat amount given by the standing waves can be uniformalized for each part of the substrate G, so that a uniform heat treatment onto the substrate G can be performed by using a microwave.

In the aforementioned heat treatment apparatus 10, a plurality of processing chambers 11 are provided, and a microwave is introduced into each of the processing chambers 11. In this case, a microwave introduction efficiency can be enhanced compared to a case where a microwave is introduced into one large processing chamber.

Further, in the aforementioned heat treatment apparatus 10, the standing waves in the processing chambers are expected to have great amplitudes just below the antenna 14. Accordingly, in the heat treatment apparatus 10, as shown in FIG. 5, the magnetrons 13 are arranged dispersely in a lengthwise direction such that the antennas do not overlap with each other when the processing chambers 11 are seen in the direction of the white arrow in FIG. 2. By doing so, it is prevented that the respective points of the standing waves having great amplitudes overlap with each other, and thus the heat amount by the standing waves can be reliably uniformalized for each part of the substrate G. In this case, it is preferable that the magnetrons 13 are disposed almost equally in the lengthwise direction while maintaining the corresponding antenna 14 to be separated by λg/4+P×λg/2 from the inner wall surface of one end or the other end of the corresponding processing chamber 11.

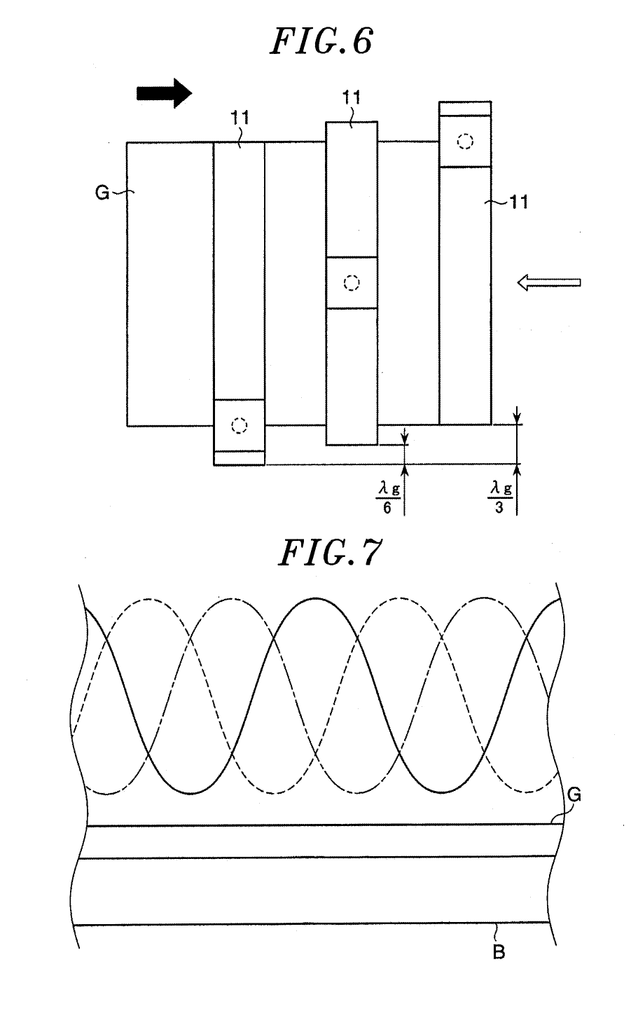

In the aforementioned heat treatment apparatus 10, the number of the processing chambers 11 is 4, but not limited thereto. The number of the processing chambers 11 may be at least 2 or more, and in this case, the adjacent processing chambers 11 may be arranged to be offset by λg/(2×n) (where n is the number of the processing chambers 11) from each other in the lengthwise direction. For example, as shown in FIG. 6, in a case where the heat treatment apparatus 10 includes 3 processing chambers 11, two processing chambers 11 are offset by λg/6 and λg/3 from the leftmost processing chamber 11 as they are positioned further away from the leftmost processing chamber 11. With respect to the phases of the standing waves, if the processing chambers 11 in FIG. are assumed, sequentially from the leftmost processing chamber 11, to be the first processing chamber 11, the second processing chamber 11 and the third processing chamber 11, as shown in FIG. 7, a phase of a standing wave (solid line) of the first processing chamber 11, a phase of a standing wave (broken line) of the second processing chamber 11, a phase of a standing wave (one dot chain line) of the third processing chamber 11 are shifted equally (by 120°) from each other in a phase (360°) of one wavelength, when the respective processing chambers 11 are seen so as to overlap with each other in a perpendicular direction to the lengthwise direction (when the respective processing chambers 11 are seen in a direction of a white arrow in FIG. 6). Even in this case, the sum of amplitudes in phases of the respective standing waves corresponding to the each part of the substrate G almost keeps a balance and the heat amount can be uniformalized for each part of the substrate G.

However, there is a concern that microwaves may leak from the gap between the processing chambers 11 and the substrate G. Then, the leaking microwaves interfere to each other in the outside of the processing chambers 11, so that there arises a possibility of exerting a bad effect on the heat treatment, e.g., causing non-uniformity of the heat treatment.

For this reason, in the heat treatment apparatus 10, timings at which the magnetrons 13 of the processing chambers 11 are turned on to generate microwaves are made to be shifted from each other.

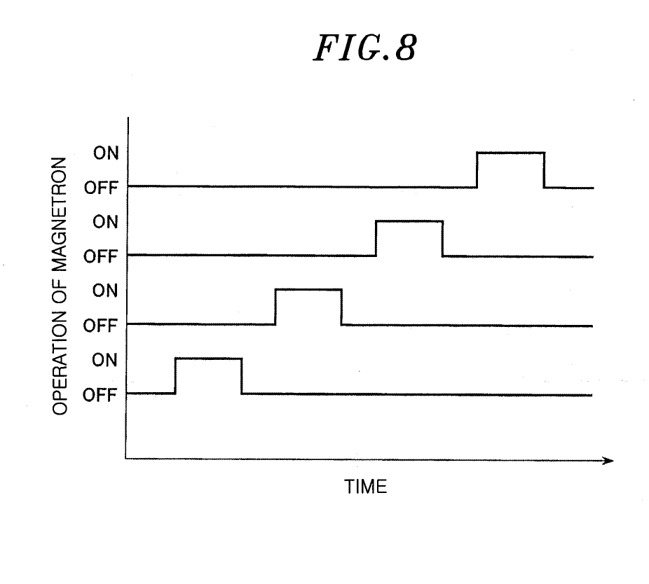

FIG. 8 is a timing chart showing timings at which microwaves are generated by the magnetrons of the processing chambers.

In FIG. 8, when the magnetron 13 of one processing chamber 11 is turned on to generate a microwave and the microwave is introduced into the one processing chamber 11, the magnetrons 13 of the other three processing chambers 11 are turned off to generate no microwave and no microwave is introduced into the other three processing chambers 11. As a result, for example, even if a microwave leaks from one processing chamber 11, there are no other microwaves that interfere with the leaking microwave, so that it can be prevented that leaking microwaves interfere with each other in the outside of the processing chambers 11.

In order to prevent the interference of the leaking microwaves, it is preferable that each of the processing chambers 11 includes a microwave leakage prevention mechanism for preventing a microwave leakage through the gap between the processing chamber 11 and the substrate G.

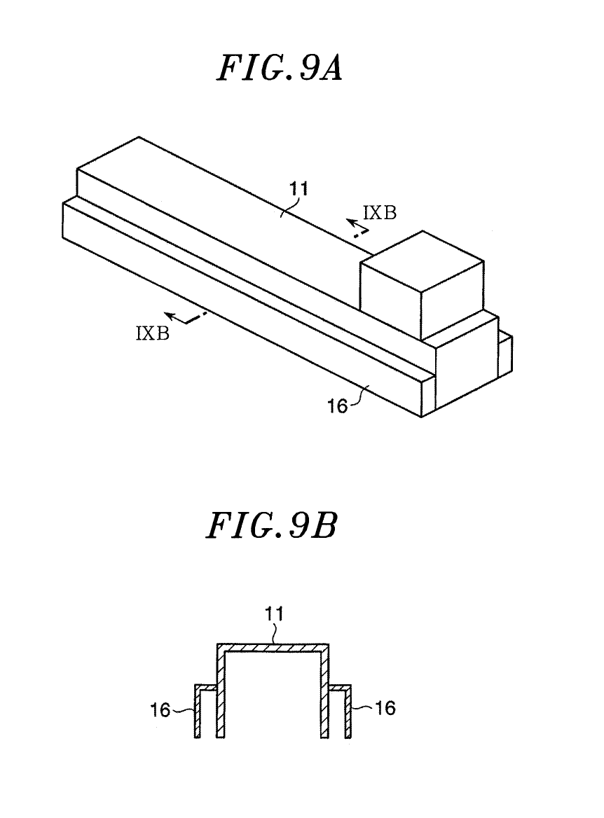

FIG. 9A is a perspective view showing a schematic configuration of one example of a processing chamber having the microwave leakage prevention mechanism. FIG. 9B is a cross-sectional view taken along a line IXB-IXB of FIG. 9A.

In FIGS. 9A and 9B, the processing chamber 11 includes groove-shaped choke structures 16, serving as the microwave leakage prevention mechanism, at both sides of the opening part 15. Each of the choke structures 16 is opened downward similarly to the opening part 15, and a depth of the groove is set to λg/4. A traveling wave of a microwave leaking through the gap between the processing chamber 11 and substrate G is incident to the grooves of the choke structures 16. At this time, a phase of a reflected wave generated by being reflected by the bottoms of the grooves is the reverse of a phase of the traveling wave. Accordingly, with respect to a traveling direction of the traveling wave, the traveling wave and the reflected wave are cancelled by each other in the outside of the choke structures 16 so that the microwave does not proceed in appearance. Therefore, a microwave can be prevented from leaking through the gap between the processing chambers 11 and the substrate G.

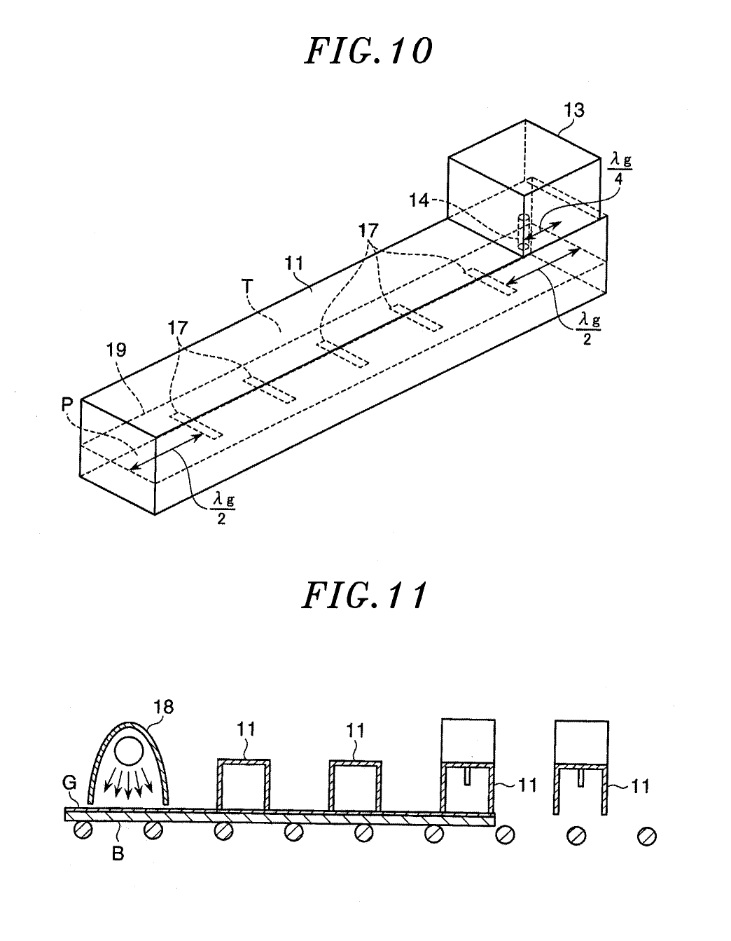

FIG. 10 is a perspective view showing a schematic configuration of another example of a processing chamber having the microwave leakage prevention mechanism.

In FIG. 10, the processing chamber 11 includes a partition wall 19 which partitions an inner space into an upper portion and a lower portion. The upper portion in the inner space partitioned by the partition wall 19 constitutes a transmission space T, and the lower portion in the inner space constitutes a processing space P. The antenna 14 of the magnetron 13 of the processing chamber 11 is disposed to be separated by λg/4 from the inner wall surface of an end portion of the processing chamber 11. The partition wall 19 has a plurality of slots 17 extended in a perpendicular direction to the lengthwise direction of the processing chamber 11. The slots 17 are disposed to be separated by s×λg/2 (where s is a positive integer) from the inner wall surface of the end portion of the processing chamber 11.

In the processing chamber 11, a microwave transmitted at a TE10 mode in the transmission space T is radiated to the processing space P through the slots 17 to become a TM11 mode. In a wall portion near the opening part 15, a current flows parallel to the gap between the processing chamber 11 and the substrate G, so that an electric field is not applied to the gap. Therefore, the microwave can be prevented from leaking through the gap between the processing chambers 11 and the substrate G.

When a microwave is irradiated into the processing chamber 11 shown in FIGS. 9A, 9B and 10, an electric field can be efficiently applied to the substrate G that is an object to be treated. Unlike a case of performing an induction heat by using a magnetic field, a selective heating can be realized, so that it is possible to efficiently heat only an amorphous silicon thin film that is a material to be treated.

While the present invention has been described by using the above embodiments, the present invention is not limited to the above embodiments.

For example, as shown in FIG. 11, a heating device 18 (preheating device) such as a lamp heater may be provided at an upstream side of the first processing chamber 11 in an arrangement direction of the processing chambers 11. In this case, the substrate G is preheated before the microwave is absorbed to the amorphous silicon thin film of the substrate G by the processing chambers 11. If the amorphous silicon is heated, doped boron or doped phosphorus is attracted into silicon molecules and polarized. Thus, the amorphous silicon becomes easy to absorb the microwave. As a result, the amorphous silicon thin film can be efficiently heated.

In the above embodiment, the heat treatment apparatus have performed a heat treatment onto the amorphous silicon thin film, but the object to be heat-treated by the heat treatment apparatus 10 is not limited thereto. As long as the object can be heated by absorbing a microwave, the object can be heat-treated by the heat treatment apparatus 10.

The present application claims priority based on Japanese Patent Application No. 2013-037138 filed on Feb. 27, 2013, and the entire contents disclosed in Japanese Patent Application No. 2013-037138 are incorporated herein by reference.

### DESCRIPTION OF REFERENCE NUMERALS

G substrate

10 heat treatment apparatus

11 processing chamber

13 magnetron

14 antenna

15 opening part

16 choke structure

17 slot

18 heating device

1. A heat treatment apparatus, comprising:
a plurality of tube-shaped processing chambers into which a microwave is introduced, the processing chambers being arranged parallel to each other and each having an opening part facing a target object,
wherein the processing chambers are disposed, when the processing chambers are seen so as to overlap with each other in a perpendicular direction to a lengthwise direction of each of the processing chambers, to be offset from each other in the lengthwise direction so that phases of standing waves generated in the processing chambers do not coincide. with each other.

2. The heat treatment apparatus of claim 1, wherein in a case where the number of the processing chambers is n, if an effective wavelength of the microwave. is assumed to be λg, the processing chambers are offset by λg/(2×n) from each other in the lengthwise direction.

3. The heat treatment apparatus of claim 1, wherein each of the processing chambers includes an antenna configured to oscillate the microwave in the corresponding processing chamber,
wherein in each of the processing chambers, a length from an inner wall surface of one end of the corresponding processing chamber in the lengthwise direction to an inner wall surface of the other end thereof is m×λg/2, where in is a positive integer, and
wherein in each of the processing chambers, the antenna is separated by λg/4+p×λg/2, where p is a positive integer including 0, from the inner wall surface of the one end or the other end in the lengthwise direction of the corresponding processing chamber.

4. The heat treatment apparatus of claim 3, wherein the antennas in the respective processing chambers are disposed so as not to overlap with each other, when the respective processing chambers are seen so as to overlap with each other in the perpendicular direction to the lengthwise direction of the respective processing chambers.

5. The heat treatment apparatus of claim 3, or wherein the antennas in the respective processing chambers are arranged at a substantially regular interval in the lengthwise direction of the respective processing chambers, when the respective processing chambers are seen so as to overlap with each other in the perpendicular direction to the lengthwise direction of the respective processing chambers.

6. The heat treatment apparatus of claim 1, wherein each of the processing chambers includes a groove-shaped choke structure at a side of the opening part, and a depth of the choke structure is λg/4.

7. The heat treatment apparatus of claim 1, wherein each of the processing chambers includes a slot formed in a partition wall, which is provided to suppress a microwave transmission from the corresponding processing chamber toward the target object in a wall portion near the opening part.

8. The heat treatment apparatus of claim 1, further comprising:
a preheating device configured to preheat the target object before the microwave is absorbed to the target object by the processing chambers.

9. A heat treatment method. to be performed in a heat treatment apparatus including a plurality of tube-shaped processing chambers into which a microwave is introduced, the processing chambers being arranged parallel to each other and each having an opening part facing a target object, the method comprising:
allowing phases of standing waves generated in the respective processing chambers, which are observed to be in an overlapped state when the processing chambers are seen so as to overlap with each other from a perpendicular direction to a lengthwise direction of the processing chambers, to be shifted from each other.

10. The heat treatment method of claim 9, wherein when the microwave is introduced into one of the processing chambers, the microwave is not introduced into the other processing chambers.

11. The heat treatment method of claim 9, wherein the target object is preheated before the microwave is absorbed to the target object by the processing chambers.
